(19) United States
(12) Patent Application Publication
(10) Pub. No.: US 2016/0322539 A1
(43) Pub. Date: Nov. 3, 2016

(54) LED PACKAGING STRUCTURE

(71) Applicant: JIANGYIN CHANGDIAN ADVANCED PACKAGING CO.,LTD, Jingyin (CN)

(72) Inventors: Li ZHANG, Jingyin (CN); Zhiming LAI, Jingyin (CN); Dong CHEN, Jingyin (CN); Jinhui CHEN, Jingyin (CN)

(21) Appl. No.: 15/104,200

(22) PCT Filed: Dec. 26, 2013
(86) PCT No.: PCT/CN2013/090483

§ 371 Date: Jun. 13, 2016

(30) Foreign Application Priority Data
Dec. 18, 2013 (CN) 201320835533.2

(51) Int. Cl. H01L 33/48; H01L 33/50; H01L 33/52; H01L 33/58; H01L 33/62; H01L 33/60

(52) U.S. Cl. CPC H01L 33/486; H01L 33/62; H01L 33/60; H01L 33/52; H01L 33/58; H01L 33/505

(57) ABSTRACT

An LED packaging structure comprises a silicon-based body and an LED chip. Discontinuous metal reflective layers are disposed on the obverse surface of the silicon-based body. A metal layer I and a metal layer II that are discontinuous are disposed in a silicon through hole. An LED chip electrode, a metal block/post, the metal reflective layer and the metal layer I are electrically connected. An LED chip electrode, a metal block/post, the metal reflective layer and the metal layer II are electrically connected. A metal layer III is located on a surface of an insulation layer II at the back of the silicon-based body and is located between the metal layer I and the metal layer II. According to the packaging structure, the LED packaging structure with omnidirectional light emission is obtained by means of a wafer level packaging technology; the LED packaging structure can reduce the thermal resistance, improve the reliability, enable the light emission angle not to be limited, and reduce design and manufacturing costs.

### FIELD OF THE INVENTION

The present utility model relates to an LED packing structure and belongs to the field of a semiconductor packing technologies.

### DESCRIPTION OF RELATED ART

Generally, packing of a Light-Emitting Diode (Light-Emitting Diode, LED for short, same as below) includes multiple packing forms. In an earlier period, a substrate is packed by using a lead frame, an LED chip is adhered to the lead frame by using thermal grease (or a conductive adhesive) and is loaded with a current in a lead bonding manner to be enabled to emit light; with the technical progress, some novel and high-performance substrate materials, such as a ceramic substrate and an AlN substrate, appear and play a leading role in application of high-power LEDs. However, for a commercial product, the following problems still exist in the existing LED packing technologies: (1) Thermal resistance is high. Because light emitting of an LED chip is exited by an electron recombination process, a great amount of heat is generated while light is emitted. It is well-known that generation of heat, in turn, affects efficiency of converting electricity into light, thereby reducing light-emitting performance of the LED. (2) The LED chip is connected to a metal reflective layer by means of a mounting technology, and because the LED chip becomes lighter, unbalance exists between wetting forces of an electrode and solder, and an improper connection manner, such as drifting, tombstoning, or rotating, may occur during refluxing, which affects reliability of LED packing. (3) A light emission angle is limited. With regard to an existing LED lamp, an LED chip thereof is located in a concave reflective cup cover, a maximum light emission angle is less than or equal to 150 degrees, and a limited light emission angle causes a limited use scope of the LED lamp, a secondary optical design structure may be used in some scenarios where an extra large angle or even a full angle is needed. Because of the light emission angles are different, the secondary optical design structures need to be designed specifically with specific light emission angles taken into consideration, which not only increases difficulty of the secondary optical design, but also increases complexity of the LED structure. Meanwhile, design and manufacturing costs are also increased accordingly.

### SUMMARY OF THE INVENTION

### Technical Problem

An objective of the present utility model is to overcome the aforementioned disadvantages to provide an LED packaging structure that can reduce the thermal resistance, improve the reliability, enable the light emission angle not to be limited, and reduce design and manufacturing costs.

### Technical Solution

The objective of the present utility model is implemented as follows:

An LED packing structure of the present utility model includes a silicon-based body having a back surface provided with several silicon through holes and an LED chip with LED chip electrodes, an insulation layer I being disposed on an obverse surface of the silicon-based body, and an insulation layer II being disposed on an inner wall of the silicon through hole, where:

metal reflective layers that are discontinuous are disposed on a surface of the insulation layer I, a top of the silicon through hole is provided with insulation layer openings that penetrate through the insulation layer I and insulation layer II, a metal layer I and a metal layer II that are discontinuous are disposed on a surface of the insulation layer II, one end of the metal layer I and one end of the metal layer II are connected to metal reflective layers respectively through the insulation layer openings, another end of the metal layer I and another end of the metal layer II extend outward along the silicon through holes to the back surface of the silicon-based body and extend in an opposite direction, the LED chip is mounted into the metal reflective layers through metal blocks/posts in an inverted manner, the LED chip electrode, metal block/post, metal reflective layer, and metal layer I are electrically connected, and the LED chip electrode, metal block/post, metal reflective layer, and metal layer II are electrically connected.

An LED packing structure of the present utility model further includes a metal layer III, where the metal layer III is located on the surface of the insulation layer II on the back surface of the silicon-based body and is located between the metal layer I and metal layer II, and the metal layer III is connected to neither of the metal layer I and metal layer II.

Optionally, a material of the metal blocks/posts is copper, and a height thereof ranges from 5 to 15 μm.

Optionally, a number of the metal blocks/posts and/or metal blocks/posts is at least two.

Optionally, metal connection layers are respectively disposed between the metal blocks/posts and LED chip electrodes.

Optionally, a material of the metal connection layers is tin or a tin alloy, and a height thereof ranges from 8 to 20 μm.

Optionally, the metal layer II is connected to the metal reflective layer through several metal posts, and the metal posts penetrate through the insulation layer II and partially or entirely enter the silicon-based body.

Optionally, a transparent layer is further included and the transparent layer is disposed above the LED chip by means of an adhesive.

Optionally, a space between the transparent layer and the silicon-based body is filled with the adhesive.

Optionally, a gap between the LED chip and the metal reflective layers is filled with a filler.

Optionally, a periphery of the LED chip is coated with a fluorescent powder adhesive layer.

The structure of the present utility model aims at improving light emission performance and heat dissipation performance and reducing design and packing costs by means of a wafer level packaging manner The LED chip is located on a flat and unfolded reflective layer and is not shielded around, and LED light rays may be emitted omnidirectionally; with regard to an LED light emission angle that is needed in actual use, subsequent secondary optical design structures may all be optimized on the basis of omnidirectional emission of LED light rays; the LED chip is connected in an inverted manner to a metal reflective layer through a copper/tin grid structure, thereby improving stability and operability of an inverted mounting technology; and a metal reflective layer II of a large proportion that is specifically disposed on a back surface of a silicon-based body quickly transmits heat generated when the LED chip works, thereby effectively reducing thermal resistance of the LED packing structure and helping improve LED performance.

### Advantageous Effect

Beneficial effects of the present utility model are:

1. The LED chip is located on a flat and unfolded reflective layer and is not shielded around, and LED light rays may be emitted omnidirectionally.

2. With regard to an LED light emission angle that is needed in actual use, subsequent secondary optical design structures may all be optimized on the basis of omnidirectional emission of LED light rays.

3. The LED chip is connected in an inverted manner to a metal reflective layer through a copper/tin grid structure, thereby improving stability and operability of an inverted mounting technology.

4. A metal reflective layer of a large proportion that is specifically disposed on a back surface of a silicon-based body quickly transmits heat generated when the LED chip works, thereby effectively reducing thermal resistance of the LED packing structure and helping improve LED performance

### BRIEF DESCRIPTION OF THE DRAWINGS

FIG. 1 is a schematic diagram of an embodiment of an LED packing structure of the present utility model;

FIG. 2 is a schematic diagram illustrating a position relationship between an LED chip and a metal reflective layer II of the embodiment of FIG. 1;

FIG. 3 is a schematic diagram illustrating a position relationship between an LED chip and a metal reflective layer II of the embodiment of FIG. 1;

FIG. 4 is a schematic diagram of a modified embodiment 1 of FIG. 1;

FIG. 5 and FIG. 6 are schematic diagrams of a modified embodiment 2 of FIG. 1; and

FIG. 7 is a schematic diagram of a modified embodiment 3 of FIG. 1.

### IN THE DRAWINGS:

silicon-based body 110

silicon through hole 111

LED chip 200

LED chip electrodes 210, 220

metal connection layers 311, 312

metal blocks/posts 321, 322

metal reflective layers 410, 420

insulation layer I 510

insulation layer II 520

insulation layer openings 501, 502

filler 610

adhesive 620

fluorescent powder adhesive layer 630

transparent layer 700

metal layer I 810

metal layer II 820

metal layer III 830

metal post 831

### DETAILED DESCRIPTION OF THE INVENTION

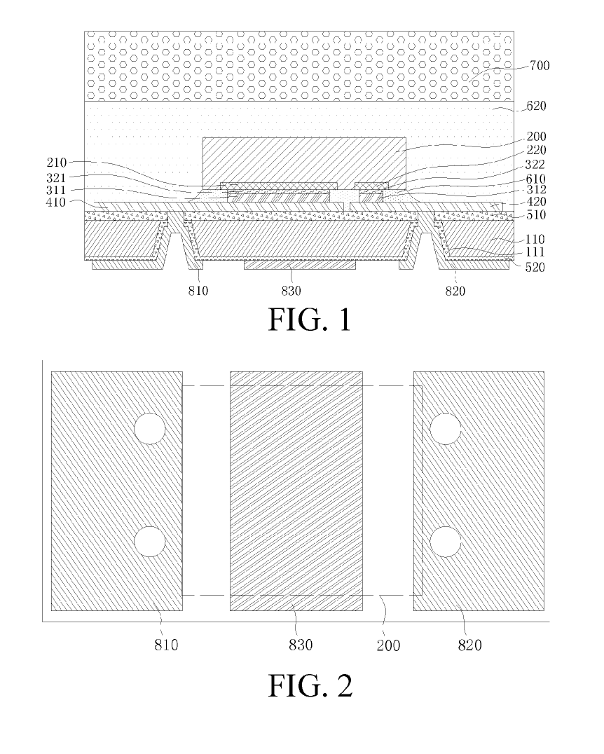

Referring to FIG. 1, the present utility model provides an LED packing structure, several silicon through holes 111 are provided on a back surface of a silicon-based body 110, an LED chip 200 has LED chip electrodes 210, 220, an insulation layer I 510 is disposed on an obverse surface of the silicon-based body 110, and an insulation layer II 520 is disposed on an inner wall of the silicon through hole 111.

Metal reflective layers 410, 420 of a material, such as silver or aluminum, are disposed on a surface of the insulation layer I 510, a metal reflective layer 410 and a metal reflective layer 420 are discontinuous, and the spacing therebetween is less than the spacing between the LED chip electrode 210 and the LED chip electrode 220. By using a high reflectivity property of a material, such as silver or aluminum metal reflective layers 410, 420 may serve as reflective layers of the LED chip 200. Because the LED chip 200 is located on a flat and unfolded reflective layer, LED light rays may be emitted omnidirectionally. There may be no substance between the LED chip 200 and the metal reflective layer 410 and metal reflective layer 420, or a filler 610 such as silica gel, may be disposed therebetween, thereby improving reliability thereof.

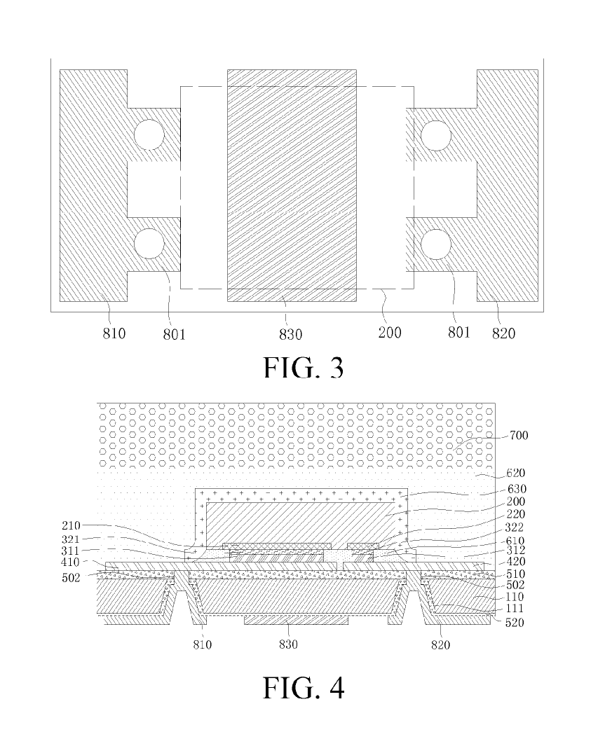

A top of the silicon through hole 111 is provided with insulation layer openings 501, 502 that penetrate through the insulation layer I 510 and insulation layer II 520, a metal layer I 810 and a metal layer II 820 that are discontinuous are disposed on a surface of the insulation layer II 520, one end of the metal layer I 810 and one end of the metal layer II 820 are connected to metal reflective layers 410, 420 respectively through the insulation layer openings 501, 502, another end of the metal layer I 810 and another end of the metal layer II 820 extend outward along the silicon through holes 111 to the back surface of the silicon-based body 110 and extend in an opposite direction, and there is a gap between the metal layer I 810 and the metal layer II 820. The metal layer I 810 and metal layer II 820 may extend on the back surface of the silicon-based body 110 to present a rectangle and may also extend to present a rectangle with protrusions 801, where a number of protrusions 801 is greater than or equal to a number of silicon through holes 111, and one protrusion 801 at least corresponds to one silicon through hole 111, as shown in FIG. 3.

The LED chip 200 is mounted into the metal reflective layers 410, 420 through metal blocks/posts 321, 322 in an inverted manner, the LED chip electrode 210, metal block/post 321, metal reflective layer 410, and metal layer I 810 are electrically connected, and the LED chip electrode 220, metal block/post 322, metal reflective layer 420, and metal layer II 820 are electrically connected. The metal layer III 830 is located on the surface of the insulation layer II 520 on the back surface of the silicon-based body 110 and is located between the metal layer I 810 and metal layer II 820, and the metal layer III 830 is connected to neither of the metal layer I 810 and metal layer II 820. The metal layer III 830 can effectively dissipate heat that is transmitted to the silicon-based body 110 when the LED chip 200 works.

A transparent layer 700 of a material, such as glass or organic resin, is fixed by using an adhesive 620, such as silica gel, above the LED chip 200, and a space between the transparent layer 700 and silicon-based body 110 is filled with the adhesive 620. The transparent layer 700 made of glass and having better weatherability helps prolong a service life of an LED lamp in an outdoor environment.

With regard to an LED packing structure of the present utility model, the following structure modifications may be made according to actual requirements.

### Modified Embodiment 1, as Shown in FIG. 7

A gap between the metal layer I 810 and the metal layer II 820 may be greater than the spacing between the electrodes 210, 220 of the LED chip, so as to enlarge an area of the metal layer III 830 to the greatest extent. Several metal posts 831 are disposed below the metal reflective layer 410, and the metal posts 831 penetrate through the insulation layer II 520 to be in direct contact with the silicon-based body 110, and may also partially or entirely enter the silicon-based body 110 so as to increase a contact area. The metal post 831 may quickly transmit heat generated when the LED chip 200 works to the metal layer III 830 on the back surface of the silicon-based body 110, so as to implement low thermal resistance from a temperature node of the LED chip 200 to a packing pin, thereby helping improve LED performance.

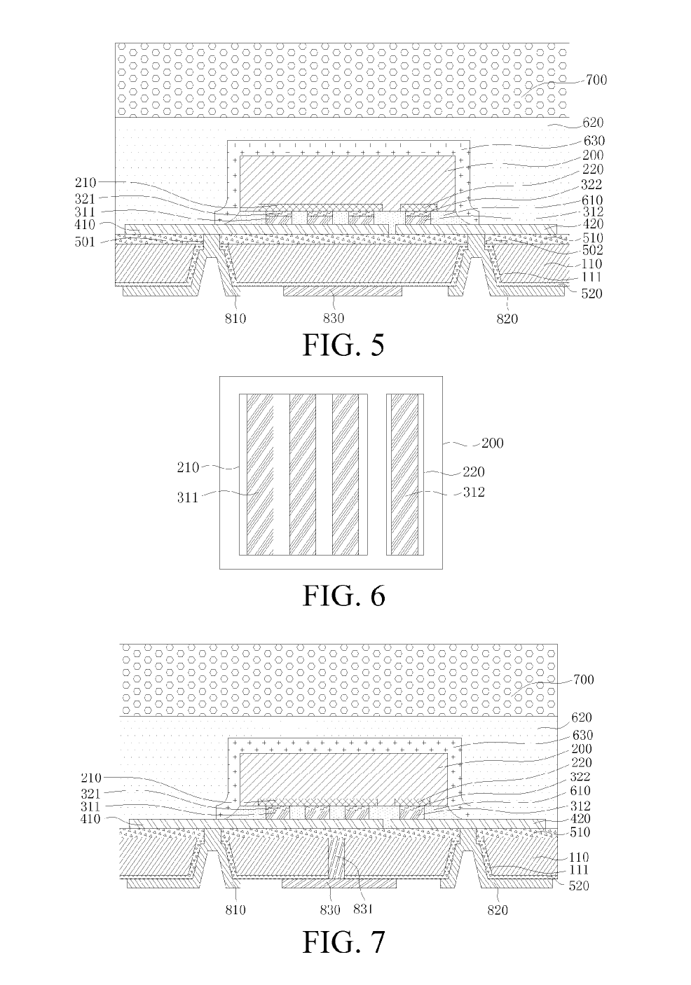

### Modified Embodiment 2, as Shown in FIG. 5, FIG. 6, and FIG. 7

A number of the metal blocks/posts 321 is at least two, the metal blocks/posts 321 are arranged in parallel and form a metal grid structure, a material thereof is copper, and a metal connection layer 311 of tin or a tin alloy is disposed thereon. A number of the metal blocks/posts 322 on another side is also at least two, the metal blocks/posts 322 are arranged in parallel and may also form a metal grid structure made of copper, and a metal connection layer 312 of tin or a tin alloy is disposed thereon. The LED chip 200 is connected in an inverted manner to metal reflective layers 410, 420 through a metal grid, thereby improving stability and operability of an inverted mounting technology, overcoming an improper connection manner, such as drifting, tombstoning, or rotating, that may occur in the LED chip 200 in a refluxing process, and ensuring consistency and evenness of a connection of the LED chip 200 in a wafer level technology process. A thickness range of the metal blocks/posts 321 and metal blocks/posts 322 is 5 to 15 μm, and a thickness range of tin or a tin alloy is 8 to 20 μm, so that thermal resistance can be reduced to the greatest extent while a reliable connection is implemented. The metal grid may also be applied to a conventional LED lamp provided with an LED reflective cup or a connection between another micro metal component and a metal surface/block.

### Modified Embodiment 3, as Shown in FIG. 4, FIG. 5, and FIG. 7

A single-color LED chip 200 generally may only excite light of three colors, namely, R (red), G (green), and B (blue). However, in actual life of people, use of white light is needed more, and to obtain a white light LED lamp, a blue LED chip 200 may be chosen to excite fluorescent powder distributed around it, and a fluorescent powder adhesive layer 630 made of the fluorescent powder may be coated onto a light emission surface of the blue LED chip 200, and the fluorescent powder may also be mixed with the adhesive 620, such as silica gel and be filled in the space between the transparent layer 700 and silicon-based body 110.

With regard to an LED packing structure of the present utility model, Embodiment 1, Embodiment 2, and Embodiment 3 of the modified structures may be freely combined according to actual requirements, thereby improving different types of performance of the LED packing structure.

The LED packing structure of the present utility model is not limited to the foregoing embodiments, and any variations, equivalent changes, and modifications made to the foregoing embodiments by any person skilled in the art according to the technical substance of the present utility model without departing from the spirit and scope of the present utility model all fall within the protect scope defined by the present utility model.

1. An LED packing structure, comprising a silicon-based body having a back surface provided with several silicon through holes and an LED chip with LED chip electrodes, an insulation layer I being disposed on an obverse surface of the silicon-based body, and an insulation layer II being disposed on an inner wall of the silicon through hole, wherein:
metal reflective layers that are discontinuous are disposed on a surface of the insulation layer I, a top of the silicon through hole is provided with insulation layer openings that penetrate through the insulation layer I and insulation layer II, a metal layer I and a metal layer II that are discontinuous are disposed on a surface of the insulation layer, one end of the metal layer I and one end of the metal layer II are connected to metal reflective layers respectively through the insulation layer openings, another end of the metal layer I and another end of the metal layer II extend outward along the silicon through holes to the back surface of the silicon-based body and extend in an opposite direction, the LED chip is mounted into the metal reflective layers through metal blocks/posts in an inverted manner, the LED chip electrode, metal block/post, metal reflective layer, and metal layer I are electrically connected, and the LED chip electrode, metal block/post, metal reflective layer, and metal layer II are electrically connected; and
further comprising a metal layer III, wherein the metal layer III is located on the surface of the insulation layer II on the back surface of the silicon-based body and is located between the metal layer I and metal layer II, and the metal layer III is connected to neither of the metal layer I and metal layer II.

2. The LED packing structure according to claim 1, wherein: a material of the metal blocks/posts is copper, and a height thereof ranges from 5 to 15 μm.

3. The LED packing structure according to claim 2, wherein: a number of the metal blocks/posts and/or metal blocks/posts is at least two.

4. The LED packing structure according to claim 3, wherein: metal connection layers are respectively disposed between the metal blocks/posts and LED chip electrodes.

5. The LED packing structure according to claim 4, wherein: a material of the metal connection layers is tin or a tin alloy, and a height thereof ranges from 8 to 20 μm.

6. The LED packing structure according to claim 1, wherein: the metal layer III is connected to the metal reflective layer through several metal posts, and the metal posts penetrate through the insulation layer II and partially or entirely enter the silicon-based body.

7. The LED packing structure according to claim 1, further comprising a transparent layer, wherein the transparent layer is disposed above the LED chip by means of an adhesive.

8. The LED packing structure according to claim 7, wherein: a space between the transparent layer and the silicon-based body is filled with the adhesive.

9. The LED packing structure according to claim 1, wherein: a gap between the LED chip and the metal reflective layers is filled with a filler.

10. The LED packing structure according to claim 1, wherein: a periphery of the LED chip is coated with a fluorescent powder adhesive layer.
